(19) United States
(12) Patent Application Publication
(10) Pub. No.: US 2009/0301560 A1
(43) Pub. Date: Dec. 10, 2009

(54) PHOTOVOLTAIC ELEMENT, PHOTOVOLTAIC MODULE AND METHOD OF MANUFACTURING PHOTOVOLTAIC ELEMENT

(75) Inventor: Takuo NAKAI, Kaizuka (JP)

Correspondence Address: MOTS LAW, PLLC, 1629 K STREET N.W., SUITE 602, WASHINGTON, DC, 20006-1635, US

(73) Assignee: SANYO ELECTRIC CO., LTD., Moriguchi (JP)

(21) Appl. No.: 12/133,555

(22) Filed: Jun. 5, 2008

(51) Int. Cl. H01L 31/00

(52) U.S. Cl. 136/256

(57) ABSTRACT

A photovoltaic element includes a power generating region having a photoelectric conversion layer, a collector formed on a surface of the power generating region and a protective layer formed on the power generating region, wherein at least a part of the protective layer is formed at a prescribed interval from a side surface of the collector without contact with the side surface.

### BACKGROUND OF THE INVENTION

1. Field of the Invention

The present invention relates to a photovoltaic element, a photovoltaic module and a method of manufacturing the photovoltaic element, and more particularly, it relates to a photovoltaic element formed with a protective layer on a power generating region, a photovoltaic module and a method of manufacturing the photovoltaic element.

2. Description of the Background Art

A photovoltaic element capable of suppressing reduction in element characteristics resulting from protection of a surface of a photoelectric conversion layer from cracks or moisture by being formed with protective layers on the surface of the photoelectric conversion layer and a method of manufacturing the same are known in general. A structure of an exemplary conventional photovoltaic element 100 will be now described with reference to FIGS. 10 to 12.

As shown in FIGS. 10 and 11, the exemplary conventional photovoltaic element 100 is formed with a collector 102 on an upper surface of a photoelectric conversion layer 101. As shown in FIG. 11, the collector 102 is constituted by finger electrode portions 102a for collecting currents generated in a photoelectric conversion layer 101 and bus bar electrode portions 102b for collecting the currents flowing through the finger electrode portions 102a. A collector (not shown) similar to the collector 102 formed on the upper surface of the photoelectric conversion layer 101 is formed on a lower surface of the photoelectric conversion layer 101.

In the exemplary conventional photovoltaic element 100, protective layers 103 are formed on the upper surface (light incident surface side) of the photoelectric conversion layer 101 as shown in FIG. 10. The protective layers 103 each have a function of suppressing cracks on the surface of the photoelectric conversion layer 101 and a function of blocking contact between the surface of the photoelectric conversion layer 101 and an atmosphere. In other words, the protective layers 103 have functions of suppressing reduction in element characteristics of the photovoltaic element 11 due to the cracks on the surface of the photoelectric conversion layer 101 and also suppressing reduction in element characteristics caused by ionization of a substance of the photoelectric conversion layer 101 due to moisture in air. The thicknesses of the protective layers 103 on regions where the protective layers 103 are in contact with the side surfaces of the collector 102 increases to an extent similar to the thickness of the collector 102 due to surface tension.

As shown in FIGS. 10 to 12, first ends of tab electrodes 104 for electrically connecting the photovoltaic elements 100 adjacent to each other are connected to upper surfaces of the bus bar electrode portions 102b of the photovoltaic element 100. Seconds ends of the tab electrodes 104 are electrically connected to bus bar electrode portions (not shown) of a collector formed on a back surface of another photovoltaic element 100 adjacent thereto.

A method of forming the protective layers 103 on the upper surface of the photoelectric conversion layer 101 will be now described with reference to FIG. 10 and FIGS. 12 to 14.

As shown in FIG. 13, mask layers 105 are formed on the upper surfaces of the bus bar electrode portions 102b of the photovoltaic element 100. As shown in FIG. 14, the mask layers 105 are employed as masks for coating a resin material constituting the protective layers 103 on the surface of the photoelectric conversion layer 101 by spraying. Thereafter the mask layers 105 are removed. Thus, the exemplary conventional photovoltaic element 100 shown in FIG. 10 is formed.

Then the first ends of the tab electrodes 104 are connected to the upper surfaces of the bus bar electrode portions 102b and the second ends of the tab electrodes 104 are connected to the bus bar electrode portions (not shown) on the back surface of the photovoltaic element 100 adjacent thereto. Thus, a plurality of the exemplary conventional photovoltaic elements 100 shown in FIG. 12 are connected to each other. Thereafter the connected plurality of photovoltaic elements 100 are modularized by filling a filler (not shown).

A photovoltaic element formed such that a thickness of a protective layer formed on a light receiving surface of the photovoltaic element is not larger than the average thickness for inhibiting air bubbles from entering into the protective layer and a method of the manufacturing the same are known in general, as disclosed in Japanese Patent Laying-Open No. 2004-228333, for example.

A structure of another exemplary conventional photovoltaic element 200 described in Japanese Patent Laying-Open No. 2004-228333 will be now described with reference to FIGS. 15 and 16.

The another exemplary conventional photovoltaic element 200 described in Japanese Patent Laying-Open No. 2004-228333 is provided with insulating members 202 on both side ends in a direction Y of the upper surface of a photovoltaic element plate 201 (photoelectric conversion layer) respectively, as shown in FIG. 15. Mold release agents 202a are applied to side surfaces of the insulating members 202 closer to a power generating region 203 as shown in FIG. 16. The mold release agents 202a each have a function of reducing surface tension of a protective layer 207 in contact with the side surfaces of the insulating members 202. As shown in FIG. 15, a plurality of collectors 204 (finger electrodes) for collecting currents generated in the photovoltaic element plate 201 are provided on an upper surface of the power generating region 203 to extend in a direction Y.

The conductive foil members 205 (bus bar electrodes) are provided on upper surfaces of the insulating members 202 separately from the collectors 204. The conductive foil members 205 are connected to the collectors 204 on the upper surfaces of the insulating members 202. The conductive foil members 205 each have a function of collecting currents flowing through the collectors 204. As shown in FIG. 16, conductive foil members 206 are provided on both side ends of a lower surface of the photovoltaic element plate 201, located at positions corresponding to the conductive foil members 205, respectively. The protective layer 207 (see FIG. 16) for protecting the photovoltaic element plate 201 from cracks or moisture is formed on the upper surface (light incident surface side) of the power generating region 203 of the photovoltaic element plate 201. The protective layer 207 is in contact with the mold release agents 202a provided on the side surfaces of the insulating members 202. Thus, the mold release agents 202a repel the protective layer 207 and the thicknesses of the protective layer 207 in the vicinities of the side surfaces of the insulating members 202 are smaller than the average thickness, as shown in FIG. 16.

A method of manufacturing the another exemplary conventional photovoltaic element 200 described in Japanese Patent Laying-Open No. 2004-228333 will be now described with reference to FIGS. 15 and 16.

The mold release agent 202a is applied to one of the side surfaces of each insulating member 202. Then the insulating members 202 are bonded to the both side ends in the direction Y (see FIG. 15) of the photovoltaic element plate 201 such that the surfaces to which the mold release agents 202a are applied are sides closer to the power generating region 203. A conductive bonding material is applied to the plurality of collectors 204 made of a copper wire and bonded onto the upper surface of the power generating region 203 of the photovoltaic element plate 201 to extend in the direction Y. At this time, the collectors 204 are bonded such that the ends thereof are located on the upper surfaces of the insulating members 202. Thereafter the conductive foil members (bus bar electrodes) 205 are bonded to the upper surfaces of the insulating members 202 so that the conductive foil members (bus bar electrodes) 205 are connected to the collectors 204.

The conductive foil members 206 are bonded to the both side ends on the lower surface of the photovoltaic element plate 201, located at positions corresponding to the conductive foil members 205.

Then the power generating region 203 on the upper surface (light incident surface side) of the photovoltaic element plate 201 is coated with a resin material forming the protective layer 207 by spraying. In the structure in Japanese Patent Laying-Open No. 2004-228333, when tab electrodes (not shown) for electrically connecting the photovoltaic elements 200 adjacent to each other are mounted on the upper surfaces of the conductive foil members 205, formation of the protective layer 207 on the upper surfaces of the conductive foil members 205 must be suppressed. In this case, mask layers 208 are conceivably formed on the upper surfaces of the conductive foil members 205 when coating the resin material. When forming the tab electrodes, the tab electrodes are mounted on the upper surfaces of the conductive foil members 205 after removing the mask layers 208 after formation of the protective layer 207.

In the exemplary conventional photovoltaic element 100 shown in FIGS. 10 to 14, however, as hereinabove described, the thicknesses of the protective layers 103 on the regions where the protective layers 103 are in contact with the side surfaces of the collector 102 are similar to the thickness of the collector 102 (bus bar electrode portions 102b) and hence the resin material forming the protective layers 103 disadvantageously penetrates between the mask layers 105 formed on the upper surfaces of the bus bar electrode portions 102b of the collector 102 in forming the protective layers 103 and the bus bar electrode portions 102b. Thus, the protective layers 103 are partially formed on the upper surfaces of the bus bar electrode portions 102b when removing the mask layers 105 after forming the protective layers 103, and hence defective connection of the tab electrodes 104 disadvantageously occurs when connecting the tab electrodes 104 to the upper surfaces of the bus bar electrode portions 102b.

In the another exemplary conventional photovoltaic element 200 described in Japanese Patent Laying-Open No. 2004-228333 shown in FIGS. 15 and 16, the thicknesses of the protective layer 207 on the regions where the protective layer 207 is in contact with the side surfaces of the insulating members 202 are not larger than the average thickness, and hence any problem similar to that of the aforementioned exemplary conventional photovoltaic element 100 does not occur. In the photovoltaic element in Japanese Patent Laying-Open No. 2004-228333, on the other hand, the mold release agents 202a disadvantageously must be applied to the side surfaces of the insulating members 202 in order to reduce the thickness of the protective layer 207 as compared with the average thickness. Thus, the manufacturing process for the photovoltaic element 200 must include a step of applying the mold release agents 202a to the side surfaces of the insulating members 202 and hence the manufacturing process is disadvantageously complicated.

### SUMMARY OF THE INVENTION

A photovoltaic element according to a first aspect of the present invention comprises a power generating region including a photoelectric conversion layer, a collector formed on a surface of the power generating region and a protective layer formed on the power generating region, wherein at least a part of the protective layer is formed at a prescribed interval from a side surface of the collector without contact with the side surface.

A photovoltaic module according to a second aspect of the present invention comprises a photovoltaic element including a power generating region having a photoelectric conversion layer, a collector formed on a first surface of the power generating region and a protective layer formed on the power generating region, wherein at least a part of the protective layer is formed at a prescribed interval from a side surface of the collector without contact with the side surface.

A method of manufacturing a photovoltaic element according to a third aspect of the present invention comprises steps of forming a power generating region including a photoelectric conversion layer, forming a collector on a surface of the power generating region and forming a protective layer on a surface of the power generating region at a prescribed interval from a side surface of a prescribed portion of the collector so as not to be in contact with the side surface. In this third aspect, the “so as not to be in contact with the side surface” means not only a case of completely being not in contact with the side surfaces but also a case of substantially being not in contact with the side surfaces.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a plan view showing a structure of a photovoltaic element according to an embodiment of the present invention;

FIG. 2 is a sectional view taken along line 400-400 in FIG. 1;

FIG. 3 is a sectional view showing a structure of a photovoltaic module including the photovoltaic elements according to the embodiment shown in FIG. 1;

FIG. 4 is a sectional view for illustrating a method of manufacturing the photovoltaic element according to the embodiment shown in FIG. 1;

FIG. 5 is a plan view for illustrating a method of manufacturing the photovoltaic element according to the embodiment shown in FIG. 1;

FIG. 6 is a sectional view taken along line 500-500 in FIG. 5;

FIG. 7 is a sectional view for illustrating a method of manufacturing the photovoltaic element according to the embodiment shown in FIG. 1;

FIG. 8 is a sectional view showing a first modification of the photovoltaic element according to the embodiment shown in FIG. 1;

FIG. 9 is a plan view showing a second modification of the photovoltaic element according to the embodiment shown in FIG. 1;

FIG. 10 is a sectional view of an exemplary conventional photovoltaic element;

FIG. 11 is a plan view of the exemplary conventional photovoltaic element shown in FIG. 10;

FIG. 12 is a sectional view showing a state where a plurality of the exemplary conventional photovoltaic elements shown in FIG. 10 are connected to each other;

FIGS. 13 and 14 are sectional views for illustrating a method of forming protective layers on a surface of the exemplary conventional photovoltaic element shown in FIG. 10;

FIG. 15 is a plan view of another exemplary conventional photovoltaic element described in Japanese Patent Laying-Open No. 2004-228333; and

FIG. 16 is a sectional view taken along line 300-300 in FIG. 15.

### DESCRIPTION OF THE PREFERRED EMBODIMENTS

Embodiment of the present invention will be hereinafter described with reference to the drawings.

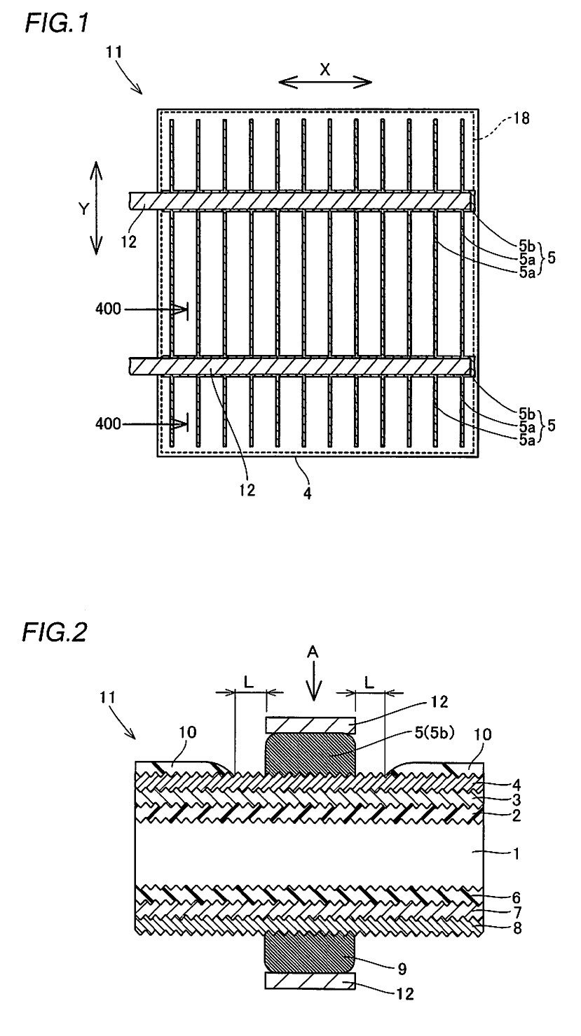

A structure of a photovoltaic element 11 according to the embodiment of the present invention will be now described with reference to FIGS. 1 and 2.

As shown in FIG. 2, the photovoltaic element 11 according to the embodiment of the present invention is formed with a substantially intrinsic i-type amorphous silicon layer 2 having a thickness of about 5 nm to about 20 nm on an n-type single-crystalline silicon substrate 1 having a thickness of about 140 μm to about 300 μm and formed with textured structures (uneven shapes) on upper and lower surfaces. The n-type single-crystalline silicon substrate 1 has a function as a power generating layer (photoelectric conversion layer). The n-type single-crystalline silicon substrate 1 is an example of the “photoelectric conversion layer” or the “first semiconductor layer” in the present invention, and the i-type amorphous silicon layer 2 is an example of the “second semiconductor layer” in the present invention. A p-type amorphous silicon layer 3 having a thickness of about 5 nm to about 20 nm is formed on the i-type amorphous silicon layer 2. The p-type amorphous silicon layer 3 is an example of the “third semiconductor layer” in the present invention.

A translucent conductive film 4 made of ITO (indium tin oxide) having a thickness of about 30 nm to about 150 nm is formed on the p-type amorphous silicon layer 3. A front collector 5 made of silver (Ag) paste is formed on a prescribed region of an upper surface of the translucent conductive film 4. The front collector 5 is constituted by a plurality of finger electrode portions 5a so formed as to extend parallel to each other in a direction Y at prescribed intervals in a direction X and bus bar electrode portions 5b aggregating currents collected by the finger electrode portions 5a and so formed as to extend in the direction X, as shown in FIG. 1. The finger electrode portions 5a and the bus bar electrode portions 5b each have a thickness of about 10 μm to about 100 μm. The bus bar electrode portions 5b each have a width of about 0.5 mm to about 3 mm (about 2 mm, for example). A surface formed with the front collector 5 (side A in FIG. 2) is a light incident surface of the photovoltaic element 11.

As shown in FIG. 2, a substantially intrinsic i-type amorphous silicon layer 6 having a thickness of about 5 nm to about 20 nm and an n-type amorphous silicon layer 7 having a thickness of about 5 nm to about 20 nm are successively formed on a lower surface of the n-type single-crystalline silicon substrate 1. The i-type amorphous silicon layer 6 is an example of the “fourth semiconductor layer” in the present invention, and the n-type amorphous silicon layer 7 is an example of the “fifth semiconductor layer” in the present invention. A translucent conductive film 8 made of an ITO film having a thickness of about 30 nm to about 150 nm is formed on a lower surface of the n-type amorphous silicon layer 7. A back collector 9 similar to the front collector 5 is formed on a lower surface of the translucent conductive film 8. The front collector 5 and the back collector 9 are each an example of the “collector” in the present invention.

As shown in FIG. 2, protective layers 10 made of acrylic resin added with silicon oxide as an additive are formed on a surface of the translucent conductive film 4 on the light incident surface side, corresponding to a power generating region 18. These protective layers 10 each have a function of suppressing cracks on the surface of the translucent conductive film 4 and a function of blocking contact between the surface of the translucent conductive film 4 and an atmosphere. In other words, the protective layers 10 are formed on an element surface of the power generating region 18 and have functions of suppressing reduction in element characteristics of the photovoltaic element 11 due to the cracks on the surface of the translucent conductive film 4 and also suppressing reduction in element characteristics caused by damage of the power generating region 18 of the photovoltaic element 11 due to moisture in air. The power generating region 18 means a planar region capable of generating power with the n-type single-crystalline silicon substrate 1 as the photoelectric conversion layer.

According to this embodiment, the protective layers 10 are formed so as not to be in contact with both side surfaces of the bus bar electrode portions 5b at distances L (about 2 mm) from the side surfaces of the bus bar electrode portions 5b, as shown in FIG. 2. Thus, regions formed with no protective layers 10 are formed in the vicinities of the both side surfaces of the bus bar electrode portions 5b in the surface of the translucent conductive film 4. The protective layers 10 are formed on regions of upper surfaces of the finger electrode portions 5a other than the regions in the vicinities of the both side surfaces of the bus bar electrode portions 5b. The surface of the translucent conductive film 4 is formed in an uneven shape so as to reflect the textured structure (uneven shape) of the n-type single-crystalline silicon substrate 1.

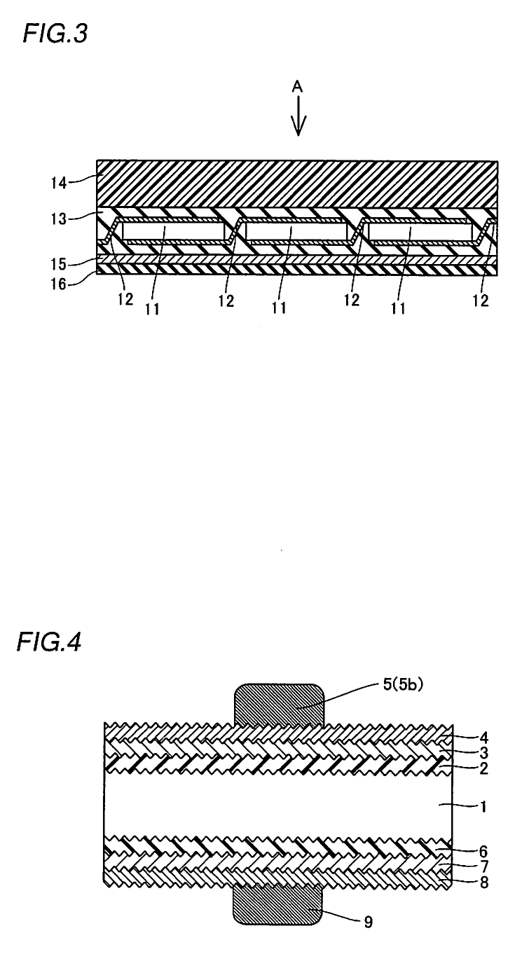

As shown in FIGS. 1 and 2, first ends of tab electrodes 12 made of copper foil for electrically connecting a plurality of the photovoltaic elements 11 are connected to upper surfaces of the bus bar electrode portions 5b of the front collector 5. Second ends of tab electrodes 12 connected to bus bar electrode portions 5b of a front collector 5 of an adjacent photovoltaic element 11 are connected to the lower surfaces of the bus bar electrode portions 5b of the back collector 9, as shown in FIGS. 2 and 3. The tab electrodes 12 are examples of the “connecting electrodes” in the present invention.

A structure of a photovoltaic module according to the embodiment will be now described with reference to FIG. 3. The photovoltaic module according to the embodiment comprises a plurality of photovoltaic elements 11, and each of the plurality of photovoltaic elements 11 is connected to another photovoltaic element 11 adjacent thereto through tab electrodes 12 folded in a stepped configuration. The photovoltaic elements 11 connected through the tab electrodes 12 are sealed with fillers 13 made of EVA (ethylene vinyl acetate) resin. A surface protector 14 made of white glass for surface protection is arranged on an upper surface (light incident surface side) of the filler 13 sealing the plurality of photovoltaic elements 11. A PET film 15 and Al foil 16 are arranged on a lower surface of another filler 13 sealing the plurality of photovoltaic elements 11 successively from a side of the photovoltaic element 11.

According to this embodiment, as hereinabove described, at least parts of the protective layers 10 are formed at intervals of the distances L from the side surfaces of the bus bar electrode portions 5b of the front collector 5 without contact with the both side surfaces of the bus bar electrode portions 5b, whereby surface tension can inhibit the thicknesses of the protective layers 10 in the vicinities of the side surfaces of the bus bar electrode portions 5b from rendering larger than the average thickness dissimilarly to the case where the protective layers 10 are in contact with the side surfaces of the bus bar electrode portions 5b. Thus, the protective layers 10 can be inhibited from being formed on portions of the upper surfaces of the bus bar electrode portions 5b, on which the tab electrodes 12 are mounted, due to the thicknesses of the protective layers 10 larger than the average thickness, and hence defective connection of the tab electrodes 12 due to formation of the protective layers 10 can be suppressed. Consequently, defective connection in mounting the tab electrodes 12 on the bus bar electrode portions 5b can be suppressed.

According to this embodiment, at least the parts of the protective layers 10 are formed at the distances L from the side surfaces of the bus bar electrode portions 5b of the front collector 5 without contact with the both side surfaces of the bus bar electrode portions 5b, whereby the thicknesses of the protective layers 10 can be inhibited from rendering larger than the average thickness without applying a mold release agent to the side surfaces of the bus bar electrode portions 5b and hence a step of applying the mold release agent can be omitted. Thus, the manufacturing process can be inhibited from complication. Therefore, according to this embodiment, defective connection in connecting the tab electrodes 12 to the bus bar electrode portions 5b can be suppressed while inhibiting the manufacturing process from complication.

According to this embodiment, the protective layers 10 are formed at the substantially equal distances L from the both side surfaces of the bus bar electrode portions 5b respectively, whereby the regions where the protective layers 10 are not in contact with the bus bar electrode portions 5b can be provided between the both side surfaces of the bus bar electrode portions 5b and the protective layers 10. Thus, the protective layers 10 can be reliably inhibited from being formed on the both side surfaces and the upper surfaces of the bus bar electrode portions 5b.

According to this embodiment, the thicknesses of the protective layers 10 in the vicinities of the both side surfaces of the bus bar electrode portions 5b are rendered smaller than the thicknesses of the bus bar electrode portions 5b, whereby the protective layers 10 can be easily inhibited from partially being formed on the portions of the upper surfaces, on which the tab electrodes 12 are mounted, by flowing through the side surfaces of the bus bar electrode portions 5b having larger thicknesses of those of the protective layers 10, even when the protective layers 10 are in contact with the side surfaces of the bus bar electrode portions 5b.

According to this embodiment, the protective layers 10 and the front collector 5 mounted with the tab electrodes 12 are formed on the surface of the translucent conductive film 4, whereby the translucent conductive film 4 can be protected by the protective layers 10 and currents generated by the photovoltaic element 11 can be effectively collected by the front collector 5 mounted with the tab electrodes 12.

According to this embodiment, the surface of the translucent conductive film 4 is formed so as to have the uneven shape, whereby a friction coefficient of the surface of the translucent conductive film 4 can be increased, and hence the protective layers 10 can be easily formed at the distances L from the side surfaces without bringing the protective layers 10 into contact with the both side surfaces of the bus bar electrode portions 5b when forming the protective layers 10.

According to this embodiment, the protective layers 10 are made of acrylic resin added with silicon oxide, whereby transparent acrylic resin can inhibit the surface of the translucent conductive film 4 on the light incident surface side from cracks, and contact between the surface of the translucent conductive film 4 and the atmosphere can be easily blocked.

According to this embodiment, the photoelectric conversion layer of the photovoltaic element 11 includes the n-type single-crystalline silicon substrate 1, the substantially intrinsic i-type amorphous silicon layer 2 formed on the first surface of the n-type single-crystalline silicon substrate 1, the p-type amorphous silicon layer 3 formed on the surface of the i-type amorphous silicon layer 2, the substantially intrinsic i-type amorphous silicon layer 6 formed on the second surface of the n-type single-crystalline silicon substrate 1 and the n-type amorphous silicon layer 7 formed on the surface of the i-type amorphous silicon layer 6 and the structure in which the protective layers 10 are formed at the prescribed intervals L from the side surfaces without contact with the side surfaces of the bus bar electrode portions 5b is applied to the photovoltaic element 11, whereby defective connection in mounting the tab electrodes 12 on the surfaces of the bus bar electrode portions 5b can be suppressed while inhibiting the manufacturing process from complication.

The manufacturing process of the photovoltaic element 11 according to the aforementioned embodiment will be now described with reference to FIGS. 1, 2 and 4 to 7.

As shown in FIG. 4, the substantially intrinsic i-type amorphous silicon layer 2 having a thickness of about 5 nm to about 20 nm and the p-type amorphous silicon layer 3 having a thickness of about 5 nm to about 20 nm are successively formed on the upper surface of the n-type single-crystalline silicon substrate 1 having a thickness of about 140 μm to about 300 μm by RF plasma CVD. Then, the substantially intrinsic i-type amorphous silicon layer 6 having a thickness of about 5 nm to about 20 nm and the n-type amorphous silicon layer 7 having a thickness of about 5 nm to about 20 nm are successively formed on the lower surface of the n-type single-crystalline silicon substrate 1 by RF plasma CVD.

The translucent conductive films 4 and 8 each having a thickness of about 30 nm to about 150 nm are formed on the surfaces of the p-type amorphous silicon layer 3 and the n-type amorphous silicon layer 7 by magnetron sputtering respectively. Thus, the surface of the translucent conductive film 4 is formed in the uneven shape so as to reflect the textured structure (uneven shape) of the n-type single-crystalline silicon substrate 1.

The comb shaped front collector 5 and back collector 9 made of Ag paste, each having a thickness of about 10 μm to about 100 μm are formed on the prescribed regions of the upper surface of the translucent conductive film 4 and the lower surface of the translucent conductive film 8 by screen printing respectively. As shown in FIG. 1, the front collector 5 is formed so as to integrally have the plurality of finger electrode portions 5a extending parallel to each other in the direction Y at the prescribed intervals in the direction X and the bus bar electrode portions 5b aggregating currents collected by the finger electrode portions 5a and extending in the direction X. The back collector 9 is formed in a manner similar to the aforementioned front collector 5.

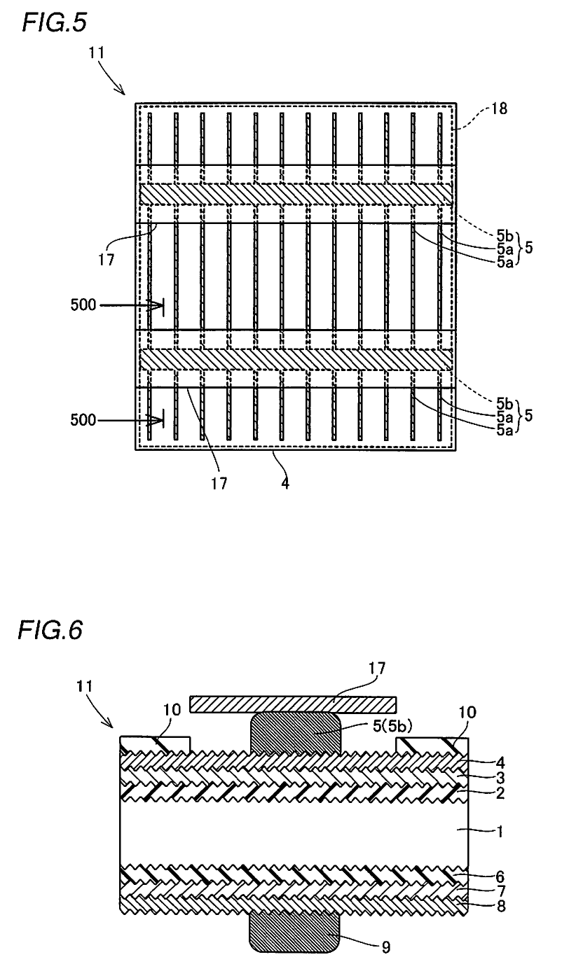

As shown in FIGS. 5 and 6, mask layers 17 made of polyester, each having a thickness of about 50 μm is formed on the upper surfaces of the bus bar electrode portions 5b of the front collector 5.

According to this embodiment, the mask layers 17 are so formed as to each have an opening width of about 6 mm larger than the widths of the bus bar electrode portions 5b (about 2 mm). At this time, the mask layers 17 each are so formed as to protrude toward a direction away from the bus bar electrode portion 5b by the substantially equal length from the both side surfaces of the bus bar electrode portion 5b, as shown in FIG. 6.

As shown in FIG. 6, acrylic resin added with silicon oxide as the additive is coated on the upper surface of the translucent conductive film 4 on the light incident surface side of the photovoltaic element 11 by spraying. Thus, the protective layers 10 are formed on the upper surface of the translucent conductive film 4 and the regions where the protective layers 10 are not formed are easily formed in the vicinities of the both side surfaces of the bus bar electrode portions 5b by the mask layers 17. Therefore, the protective layers 10 are formed at prescribed intervals from the side surfaces on the surface of the translucent conductive film 4, corresponding to the power generating region 18 without contact with the both side surfaces of the bus bar electrode portions 5b.

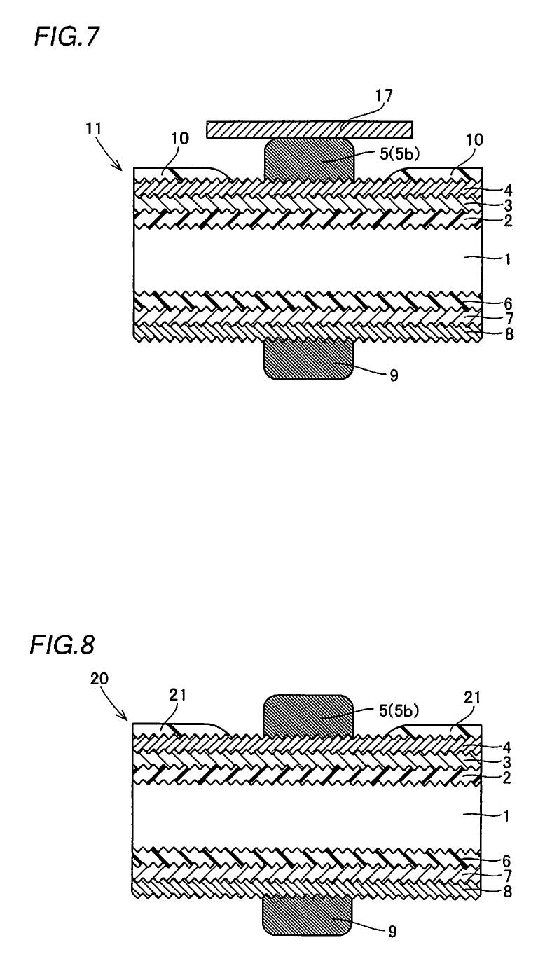

The protective layers 10 are not hardened directly after the protective layers 10 are formed and hence the protective layers 10 are a little widened toward the side surfaces of the bus bar electrode portions 5b as shown in FIG. 7 and thereafter the protective layers 10 are hardened. The distances L between the protective layers 10 and the side surfaces of the bus bar electrode portions 5b after the protective layers 10 are hardened are each about 2 mm. The thicknesses of the protective layers 10 in the vicinities of the side surfaces of the bus bar electrode portions 5b after hardening are rendered smaller than the thicknesses of the bus bar electrode portions 5b. Thus, the protective layers 10 are reliably inhibited from contact with the side surfaces of the bus bar electrode portions 5b.

Finally, the mask layers 17 formed on the bus bar electrode portions 5b are removed, thereby forming the photovoltaic element 11 according to the present invention shown in FIG. 2.

A method of modularizing a plurality of the photovoltaic element 11 formed in the aforementioned manner will be now described with reference to FIGS. 1 to 3. As shown in FIGS. 1 to 3, the first ends of the tab electrodes 12 made of copper foil are connected to the bus bar electrode portions 5b of the front collector 5 of the plurality of photovoltaic elements 11 formed in the aforementioned manner. Then the second ends of the tab electrodes 12 are connected to bus bar electrode portions (not shown) of back collector 9 of another photovoltaic element 11 adjacent thereto, as shown in FIGS. 2 and 3. Thus, the plurality of photovoltaic elements 11 are serially connected to each other as shown in FIG. 3.

An EVA sheet for forming the filler 13, the plurality of photovoltaic elements 11 connected to each other through the tab electrodes 12, another EVA sheet for forming another filler 13, the PET film 15 and the Al foil 16 are successively stacked on the surface protector 14 made of white glass. Thereafter a vacuum laminating process is performed while heating, thereby forming the photovoltaic module according to this embodiment shown in FIG. 3.

According to this embodiment, as hereinabove described, the method comprises a step of forming the mask layers 17 each having an opening with a width larger than the width of each bus bar electrode portion 5b on the upper surfaces of the bus bar electrode portions 5b of the front collector 5 and a step of forming the protective layers 10 on the surface of the translucent conductive film 4, corresponding to the power generating region 18 by employing the mask layers 17 as masks, whereby the protective layers 10 can be easily formed on the surface of the translucent conductive film 4, corresponding to the power generating region 18 at the distances L from the side surfaces without contact with the both side surfaces of the bus bar electrode portions 5b.

Although the present invention has been described and illustrated in detail, it is clearly understood that the same is by way of illustration and example only and is not to be taken by way of limitation, the spirit and scope of the present invention being limited only by the terms of the appended claims.

For example, while the protective layers are formed on the surface on the light incident surface side of the photovoltaic element by coating the acrylic resin added with silicon oxide by spraying in the aforementioned embodiment, the present invention is not restricted to this but protective layers 21 may be formed on a surface of a light incident surface side of a photovoltaic element 20 by screen printing as in a first modification shown in FIG. 8. In this case, no mask layer may be formed on upper surfaces of bus bar electrode portions 5b when forming the protective layers 21 and hence the manufacturing process can be further simplified. Various methods such as a dip method or a roll coater method other than screen printing may be employed as a method of forming the protective layers on the surface on the light incident surface side of the photovoltaic element.

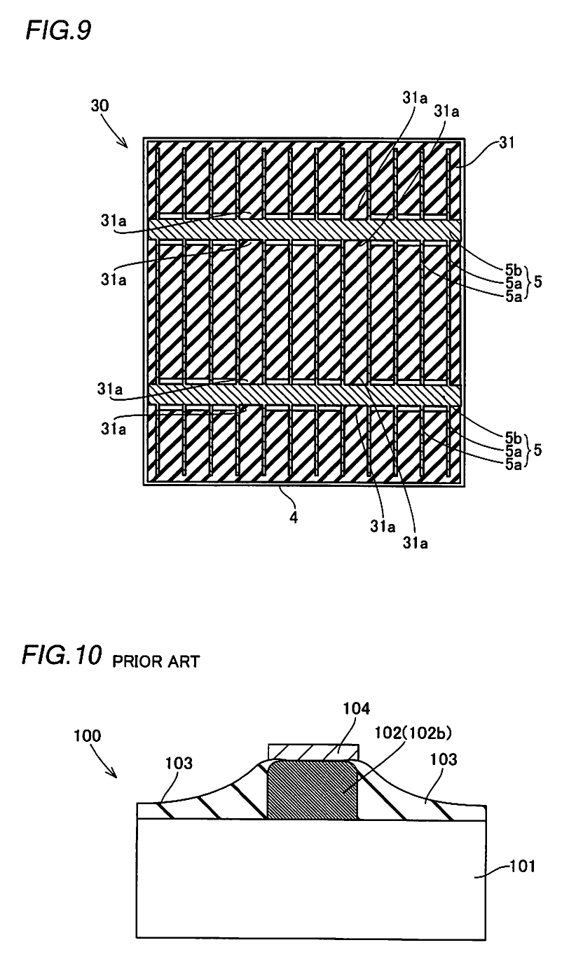

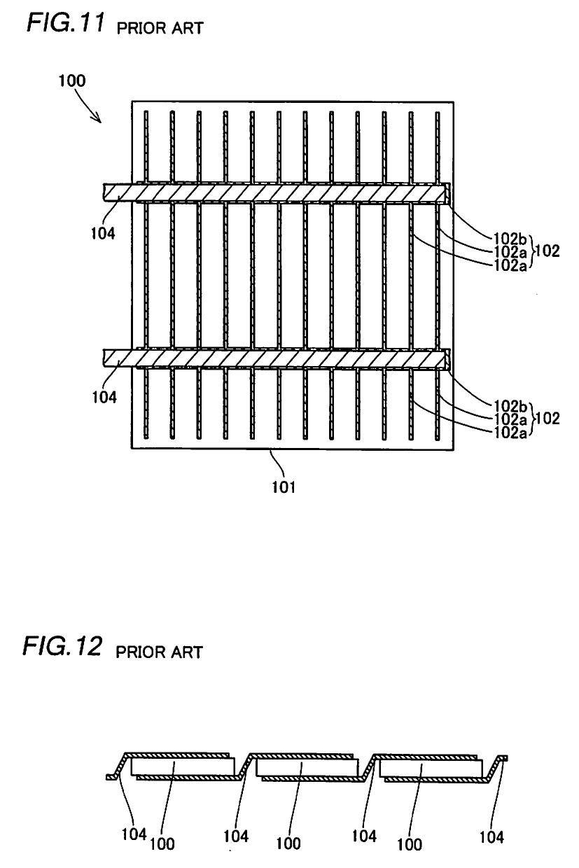

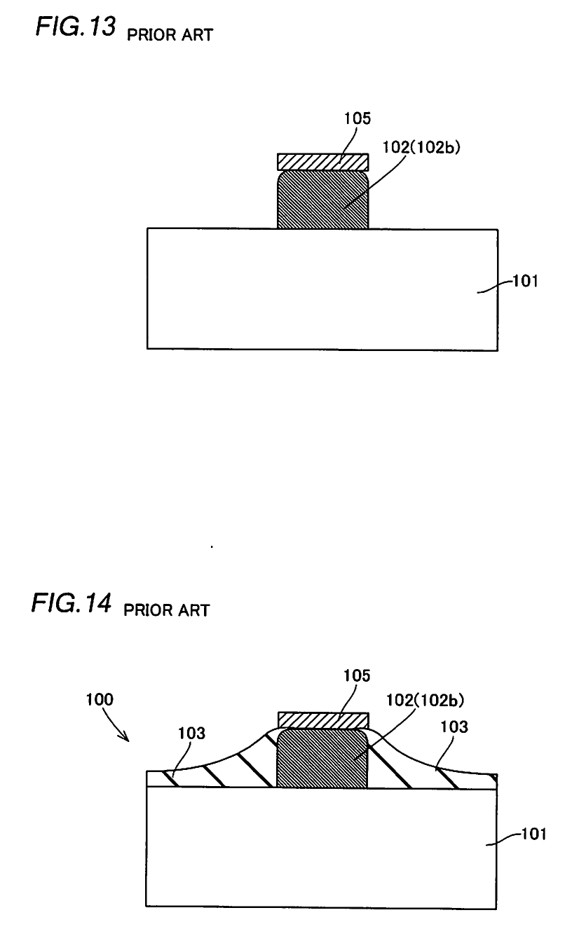

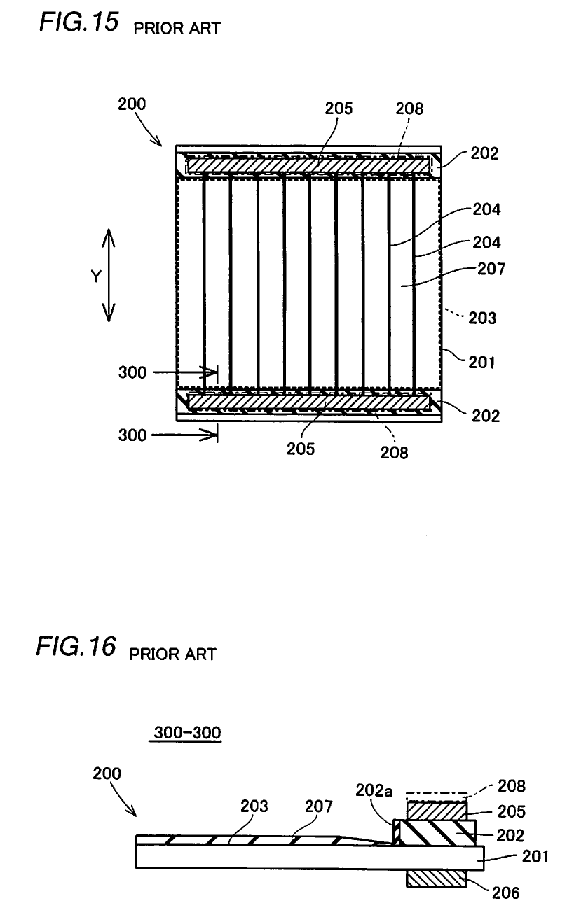

While the protective layers are formed at the distances L from the side surfaces without contact with the both side surfaces of the bus bar electrode portions in the aforementioned embodiment, the present invention is not restricted to this but the protective layers 31 may be formed to provide contact regions 31a where the side surfaces of the bus bar electrode portions 5b and the protective layers 31 are in contact with each other at prescribed intervals as in a second modification shown in FIG. 9.

While the protective layer are formed on the surface of the translucent conductive film, corresponding to the power generating region at the intervals of about 2 mm (distances L) from the side surfaces of the bus bar electrode portions without contact with the side surfaces of the bus bar electrode portions in the aforementioned embodiment, the present invention is not restricted to this but the distances L between the protective layers and the side surfaces of the bus bar electrode portions may be intervals of other than 2 mm so far as the protective layers are formed so as not to be in contact with the bus bar electrode portions. The regions where the protective layers are formed are preferably an overall surface of the power generating region in view of the function of the protective layer, that is, suppressing damage prevention of the element surface and contact between the element surface and the atmosphere.

While the surface of the translucent conductive film of the photovoltaic element is formed in the uneven shape in the aforementioned embodiment, the present invention is not restricted to this but the surface of the translucent conductive film may not be formed in the uneven shape.

While the protective layers are formed on the translucent conductive film on the light incident surface side of the photovoltaic element in the aforementioned embodiment, the present invention is not restricted to this but the protective layers may be formed on a surface on the light incident surface side of the photovoltaic element, where no translucent conductive film is provided, corresponding to the power generating region.

While the n-type single-crystalline silicon substrate having the textured structure (uneven shape) on the upper and lower surfaces is employed in the aforementioned embodiment, the present invention is not restricted to this but the n-type single-crystalline silicon substrate having no textured structure may be employed.

While the photoelectric conversion layers including the i-type amorphous silicon layers are employed between the n-type single-crystalline silicon substrate and the p-type amorphous silicon layer and between the n-type single-crystalline silicon substrate and the n-type amorphous silicon layer in the aforementioned embodiment, the present invention is not restricted to this but photoelectric conversion layers including no i-type amorphous silicon layer may be employed. The present invention can be applied to various photovoltaic elements such as a single-crystalline photovoltaic element and an amorphous photovoltaic element other than the aforementioned photovoltaic element and also applied to photovoltaic elements other than the silicon photovoltaic element.

While the protective layers are made of the acrylic resin added with silicon oxide as the additive in the aforementioned embodiment, the present invention is not restricted to this but the protective layer may be made of one of acrylic resin, epoxy resin, silicon resin, EVA, PVA (poly vinyl alcohol), PVB (poly vinyl butyral) and poly silazane, or two or more mixed resin, or made of resin mainly composed at least one of the aforementioned resin added with silicon oxide, aluminum oxide, magnesium oxide, titanium oxide or zinc oxide as the additive. The additive may be a substance other than the above, so far as the additive is metal oxide which the photovoltaic element does not substantially absorb light having a wavelength reflecting for absorption and power generation. The additive may be organic compound.

While the mask layers made of polyester are employed as the mask layers in the aforementioned embodiment, the present invention is not restricted to this but mask layers made of a material other than polyester may be employed so far as the mask layers can be masked so as not to form the protective layers on the upper surfaces of the bus bar electrode portions.

While the collector constituted by the two bus bar electrode portions and the plurality of bus bar electrode portions is employed in the aforementioned embodiment, the present invention is not restricted to this but one or at least three bus bar electrode portion constituting the collector may be employed. The collector may be formed by a structure such as a wire other than the aforementioned structure.

While the protective layers having functions of suppressing cracks on the surface of the translucent conductive film and blocking contact between the surface of the translucent conductive film and the atmosphere are formed on the surface of the translucent conductive film corresponding to the power generating region in the aforementioned embodiment, the present invention is not restricted to this but protective layer on the photovoltaic element according to the present invention may have a function other than the aforementioned functions.

What is claimed is:

1. A photovoltaic element comprising:
a power generating region including a photoelectric conversion layer;
a collector formed on a surface of said power generating region; and
a protective layer formed on said power generating region, wherein
at least a part of said protective layer is formed at a prescribed interval from a side surface of said collector without contact with said side surface.

2. The photovoltaic element according to claim 1, wherein
said protective layer is formed at prescribed intervals from both side surfaces of a prescribed portion of said collector without contact with said both side surfaces of said prescribed portion.

3. The photovoltaic element according to claim 2, wherein
said protective layer is so formed at said prescribed intervals of substantially equal lengths from said both side surfaces of said prescribed portion.

4. The photovoltaic element according to claim 1, wherein
said collector includes finger electrode portions for collecting currents generated in said power generating region and a bus bar electrode portion further collecting currents flowing through said finger electrode portion, and
said protective layer is formed at prescribed intervals from both side surfaces of said bus bar electrode portion without contact with said both side surfaces.

5. The photovoltaic element according to claim 4, wherein
thicknesses of said protective layer in the vicinities of said both side surfaces of said bus bar electrode portion are smaller than a thickness of said bus bar electrode portion.

6. The photovoltaic element according to claim 1, further comprising a translucent conductive film formed on a surface of said photoelectric conversion layer, wherein
said protective layer and said collector are formed on a surface of said translucent conductive film.

7. The photovoltaic element according to claim 6, wherein
said surface of said translucent conductive film is formed in an uneven shape.

8. The photovoltaic element according to claim 1, wherein
said protective layer is made of acrylic resin added with silicon oxide.

9. The photovoltaic element according to claim 1, wherein
said photoelectric conversion layer includes a first conductive type first semiconductor layer, a substantially intrinsic second semiconductor layer formed on a first surface of said first semiconductor layer, a second conductive type third semiconductor layer formed on a surface of said second semiconductor layer, a substantially intrinsic fourth semiconductor layer formed on a second surface of said first semiconductor layer and a first conductive type fifth semiconductor layer formed on a surface of said fourth semiconductor layer.

10. A photovoltaic module comprising a photovoltaic element including a power generating region having a photoelectric conversion layer, a collector formed on a first surface of said power generating region and a protective layer formed on said power generating region, wherein at least a part of said protective layer is formed at a prescribed interval from a side surface of said collector without contact with said side surface.

11. A method of manufacturing a photovoltaic element, comprising steps of
forming a power generating region including a photoelectric conversion layer;
forming a collector on a surface of said power generating region; and
forming a protective layer on said surface of said power generating region at a prescribed interval from a side surface of a prescribed portion of said collector so as not to be in contact with said side surface.

12. The method of manufacturing a photovoltaic element according to claim 11, further comprising steps of:
forming a mask layer having an opening with a width larger than a width of said prescribed portion of said collector on a surface of said prescribed portion of said collector; and
forming a protective layer on said surface of said power generating region by employing said mask layer as a mask.

13. The method of manufacturing a photovoltaic element according to claim 12, wherein
said step of forming said protective layer includes a step of forming said protective layer on said surface of said power generating region by employing said mask layer as a mask by spraying.

14. The method of manufacturing a photovoltaic element according to claim 12, wherein
said step of forming said mask layer includes a step of forming said mask layer so as to protrude by substantially equal prescribed lengths from both of said side surfaces of said prescribed portion of said collector.

15. The method of manufacturing a photovoltaic element according to claim 11, further comprising a step of forming a translucent conductive film on a surface of said photoelectric conversion layer, wherein
said protective layer and said collector are formed on a surface of said translucent conductive film.

16. The method of manufacturing a photovoltaic element according to claim 15, wherein
said step of forming said translucent conductive film includes a step of forming said translucent conductive film such that said surface of said translucent conductive film is formed in an uneven shape by magnetron sputtering.

17. The method of manufacturing a photovoltaic element according to claim 11, wherein
said step of forming said collector includes a step of forming said collector by integrally forming finger electrode portions for collecting currents generated in said power generating region and a bus bar electrode portion further collecting currents flowing through said finger electrode portion, and
said step of forming said protective layer includes a step of forming said protective layer at prescribed intervals from both side surfaces of said bus bar electrode portion without contact with said both side surfaces.

18. The method of manufacturing a photovoltaic element according to claim 17, wherein
said step of forming said protective layer includes a step of forming said protective layer such that thicknesses of said protective layer in the vicinities of said both side surfaces of said bus bar electrode portion are smaller than a thickness of said bus bar electrode portion.

19. The method of manufacturing a photovoltaic element according to claim 11, wherein
said step of forming said protective layer includes a step of forming said protective layer by screen printing.

20. The method of manufacturing a photovoltaic element according to claim 11, wherein
said step of forming said power generating region includes a step of forming said photoelectric conversion layer including a first conductive type first semiconductor layer, a substantially intrinsic second semiconductor layer formed on a first surface of said first semiconductor layer, a second conductive type third semiconductor layer formed on a surface of said second semiconductor layer, a substantially intrinsic fourth semiconductor layer formed on a second surface of said first semiconductor layer, a first conductive type fifth semiconductor layer formed on a surface of said fourth semiconductor layer.
